(19) United States
(12) Patent Application Publication
(10) Pub. No.: US 2024/0429022 A1
(43) Pub. Date: Dec. 26, 2024

(54) MULTIPLE CHARGED PARTICLE BEAM WRITING APPARATUS AND MULTIPLE CHARGED PARTICLE BEAM WRITING METHOD

(71) Applicant: NuFlare Technology, Inc., Yokohama-shi (JP)

(72) Inventors: Yasuo KATO, Yokohama-shi (JP); Ryoh KAWANA, Yokohama-shi (JP)

(73) Assignee: NuFlare Technology, Inc., Yokohama-shi (JP)

(21) Appl. No.: 18/823,820

(22) Filed: Sep. 4, 2024

Related U.S. Application Data
(63) Continuation of application No. PCT/JP2023/005289, filed on Feb. 15, 2023.

(30) Foreign Application Priority Data
Mar. 8, 2022 (JP) 2022-035611

(51) Int. Cl. H01J 37/317; H01J 37/304

(52) U.S. Cl. CPC H01J 37/3177; H01J 37/3045; H01J 2237/0435; H01J 2237/24514; H01J 2237/31761

(57) ABSTRACT

A multiple charged particle beam writing apparatus includes a dose-data-for-defect-position-generation-circuit to generate dose-data-for-defect which defines a dose for a defect at the defect position when the dose of the nonzero value is defined in the vicinal region, and a writing mechanism to write patterns on a sample using multiple charged particle beams, wherein, when performing the writing, a unit region where writing processing is to be performed is moved to a next unit region where a pattern was determined to exist, skipping a unit region where no pattern was determined to exist by a pattern-existence-determination-circuit, and correction is performed to reduce an excessive dose, resulting from the defective beam at any writing pass in plural writing passes of multiple writing, at another writing pass.

### CROSS-REFERENCE TO RELATED APPLICATION

This application is a continuation application based upon and claims the benefit of priority from prior Japanese Patent Application No. 2022-035611 (application number) filed on Mar. 8, 2022 in Japan, and International Application PCT/JP2023/005289, the International Filing Date of which is Feb. 15, 2023. The contents described in JP2022-035611 and PCT/JP2023/005289 are incorporated herein by reference.

### BACKGROUND OF THE INVENTION

### Field of the Invention

Some aspects of embodiments of the present invention relate to a multiple charged particle beam writing apparatus and a multiple charged particle beam writing method. For example, they relate to a method for reducing a dimensional deviation of a pattern written using multiple beams.

### Description of Related Art

The lithography technique which advances miniaturization of semiconductor devices is extremely important as a unique process whereby patterns are formed in semiconductor manufacturing. In recent years, with high integration of LSI, the line width (critical dimension) required for semiconductor device circuits is becoming increasingly narrower year by year. The electron beam writing technique, which intrinsically has excellent resolution, is used for writing or “drawing” a mask pattern on a mask blank with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multiple beam writing, the dose of each beam is controlled based on an irradiation time. However, since it may be difficult to control the irradiation time due to failures of a blanking control mechanism, etc., a defective beam irradiating a target object with an excessive dose may be generated. If a target object is not irradiated with a required dose, a problem occurs that a shape error of a pattern formed on the target object is generated. To solve this problem, a method has been proposed in which an excessive dose resulting from a defective beam is shared by peripheral beams of the defective beam in order to perform correction (e.g., refer to Japanese Patent Application Laid-open (JP-A) No. 2020-021919).

### BRIEF SUMMARY OF THE INVENTION

According to one aspect of the present invention, a multiple charged particle beam writing apparatus includes
a beam forming mechanism configured to form multiple charged particle beams,
a dose data generation circuit configured to generate, for each processing region of a plurality of processing regions obtained by dividing a writing region on a surface of a target object, dose data which defines an individual dose of each position in a processing region concerned,
a dose determination circuit configured to perform, for the each processing region, a determination of whether a position where a dose of a nonzero value is defined exists in a vicinal region including a defect position to be irradiated with a defective beam whose dose is excessive in the multiple charged particle beams,
a dose-data-for-defect-position generation circuit configured to generate dose-data-for-defect which defines a dose for a defect at the defect position in a case where the dose of the nonzero value is defined in the vicinal region,
a pattern existence determination circuit configured to perform, for each unit region on the surface of the target object where an irradiation region of the multiple charged particle beams is set, a determination of whether a pattern to be arranged in a unit region concerned exists, using dose data of each position to be irradiated in the unit region concerned, and
a writing mechanism configured to perform writing a pattern on the target object using the multiple charged particle beams, wherein,
in a case of performing the writing, a unit region in which writing processing is to be performed is moved to a next unit region in which a pattern was determined to exist, skipping a unit region in which no pattern was determined to exist by the pattern existence determination circuit, and correction is performed to reduce an excessive dose, resulting from the defective beam at any writing pass in a plurality of writing passes of multiple writing, at another writing pass.

According to another aspect of the present invention, a multiple charged particle beam writing method includes
forming multiple charged particle beams,
generating, for each processing region of a plurality of processing regions obtained by dividing a writing region on a surface of a target object, dose data which defines an individual dose of each position in a processing region concerned,
performing, for the each processing region, a determination of whether a position where a dose of a nonzero value is defined exists in a vicinal region including a defect position to be irradiated with a defective beam whose dose is excessive in the multiple charged particle beams,
generating dose-data-for-defect which defines a dose for a defect at the defect position in a case where the dose of the nonzero value is defined in the vicinal region,
performing, for each unit region on the surface of the target object where an irradiation region of the multiple charged particle beams is set, a determination of whether a pattern to be arranged in a unit region concerned exists, using dose data of each position to be irradiated in the unit region concerned, and
performing writing a pattern on the target object using the multiple charged particle beams, wherein,
in a case of the performing writing, a unit region in which writing processing is to be performed is moved to a next unit region in which a pattern was determined to exist, skipping a unit region in which no pattern was determined to exist, and correction is performed to reduce an excessive dose, resulting from the defective beam at any writing pass in a plurality of writing passes of multiple writing, at another writing pass.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram illustrating an example of a writing operation according to the first embodiment;

FIG. 5 is an illustration showing an example of an irradiation region of multiple beams and a pixel to be written according to the first embodiment;

FIG. 6 is an illustration showing an example of a writing method of multiple beams according to the first embodiment;

FIG. 7 is an illustration showing an example of “with or without” a pattern at each writing pass according to the first embodiment;

FIG. 8 is a flowchart showing an example of main steps of a writing method according to the first embodiment;

FIG. 9A is an illustration showing a beam position deviation and a position deviation periodicity according to the first embodiment;

FIG. 9B is an illustration showing a beam position deviation and a position deviation periodicity according to the first embodiment;

FIG. 10A is an illustration showing an example of a method for correcting a position deviation according to the first embodiment;

FIG. 10B is an illustration showing an example of a method for correcting a position deviation according to the first embodiment;

FIG. 11A is an illustration showing an example of correction of a defective beam according to the first embodiment;

FIG. 11B is an illustration showing an example of correction of a defective beam according to the first embodiment;

FIG. 12 is an illustration showing another example of correction of a defective beam according to the first embodiment;

FIG. 13 is an illustration showing an example of “with or without” a pattern in a processing region and that in each main deflection region according to a comparative example of the first embodiment;

FIG. 14 is an illustration showing an example of “with or without” a pattern in a processing region and that in each main deflection region according to the first embodiment;

FIG. 15 is an illustration showing a flowchart of main steps of a writing method according to a third embodiment;

FIG. 16 is an illustration showing a flowchart of main steps of a writing method according to a fourth embodiment;

FIG. 17 is a conceptual diagram showing a configuration of a writing apparatus according to a fifth embodiment; and

FIG. 18 is an illustration showing a flowchart of main steps of a writing method according to the fifth embodiment.

### DETAILED DESCRIPTION OF THE INVENTION

There has been studied a method of correcting an excessive dose caused by a defective beam, performed across the writing passes of multiple writing, although which may not yet be publicly known at the priority date of the present application. In the case of writing with multiple beams, for example, the writing proceeds while shifting (displacing) a rectangular region irradiated with the multiple beams in the writing region of the target object. In such a case, writing processing for a rectangular region where no pattern exists is preferably skipped in order to reduce the writing time.

However, when correction of an excessive dose due to a defective beam is performed across the writing passes of multiple writing, there may be a case, in some writing passes, where a rectangular region including a position irradiated with a defective beam does not have any pattern. With regard to dose data, it is generated independently among writing passes. The data generation is carried out on the premise that correcting a defect is performed in the first writing pass in order to correct the position irradiated with a defective beam in the second writing pass, for example. However, there is a possibility that the rectangular region including the position irradiated with a defective beam in the second writing pass is a region without a pattern. In that case, if the writing processing for the region without a pattern is skipped, irradiation of the defective beam to be emitted in the second writing pass is not performed. Therefore, the premise of correction at the first writing pass is broken. Consequently, a problem occurs in that an unnecessary correction for a defect is carried out.

Embodiments below provide an apparatus and method which can avoid unnecessary correction of a defect in the case of correcting, across the writing passes of multiple be writing, an excessive dose caused by a defective beam.

Embodiments below describe a configuration in which an electron beam is used as an example of a charged particle beam. The charged particle beam is not limited to the electron beam, and other charged particle beam such as an ion beam may also be used.

### First Embodiment

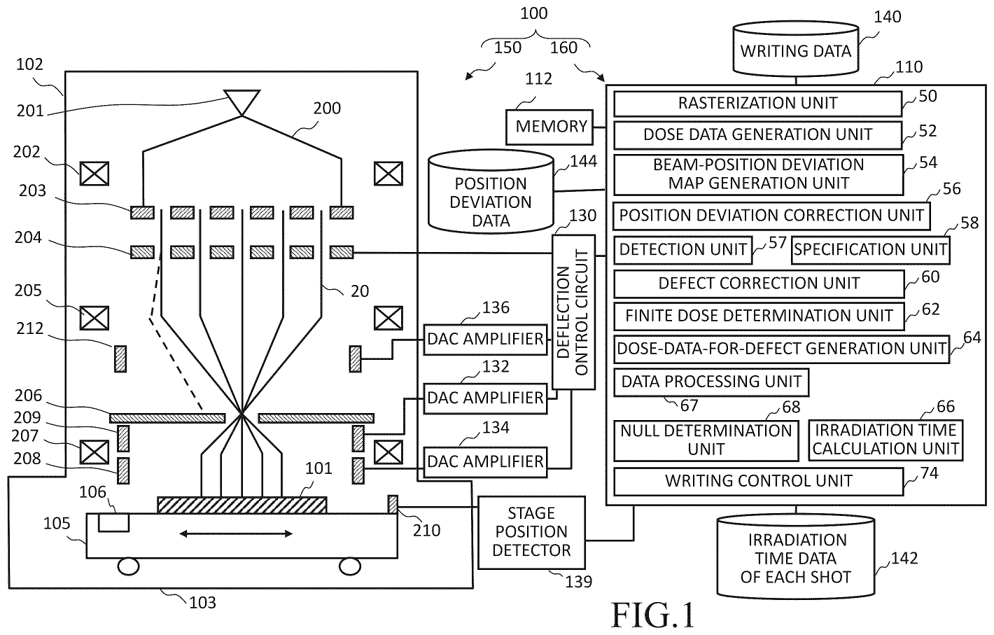

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus. The writing mechanism 150 includes an electron beam column 102 (multiple electron beam column) and a writing chamber 103. In the electron beam column 102, there are disposed an electron gun 201, an illumination lens 202, a shaping aperture array substrate 203, a blanking aperture array mechanism 204, a reducing lens 205, a collective blanking deflector 212, a limiting aperture substrate 206, an objective lens 207, a deflector 208, and a deflector 209. In the writing chamber 103, an XY stage 105 is disposed. On the XY stage 105, there is placed a target object or “sample” 101 such as a mask blank, on which resist has been applied, serving as a writing target substrate when writing is performed. The target object 101 is, for example, an exposure mask used in fabricating semiconductor devices, or a semiconductor substrate (silicon wafer) for fabricating semiconductor devices. Further, on the XY stage 105, a mirror 210 for measuring the position of the XY stage 105 is placed. Furthermore, a Faraday cup 106 is placed on the XY stage 105.

The control system circuit 160 includes a control computer 110, a memory 112, a deflection control circuit 130, DAC (digital-analog converter) amplifier units 132, 134 and 136, a stage position detector 139, and storage devices 140, 142, and 144 such as magnetic disk drives. The control computer 110, the memory 112, the deflection control circuit 130, the DAC amplifier units 132, 134 and 136, the stage position detector 139, and the storage devices 140, 142, and 144 are connected to each other through a bus (not shown). The DAC amplifier units 132, 134 and 136 and the blanking aperture array mechanism 204 are connected to the deflection control circuit 130. Outputs of the DAC amplifier unit 132 are connected to the deflector 209. Outputs of the DAC amplifier unit 134 are connected to the deflector 208. Outputs of the DAC amplifier unit 136 are connected to the collective blanking deflector 212. The deflector 208 is composed of at least four electrodes (or “poles”), and controlled by the deflection control circuit 130 through a corresponding amplifier, disposed for each electrode, of the DAC amplifier unit 134. The deflector 209 is composed of at least four electrodes (or “poles”), and controlled by the deflection control circuit 130 through a corresponding amplifier, disposed for each electrode, of the DAC amplifier unit 132. The collective blanking deflector 212 is composed of at least two electrodes (or “poles”), and controlled by the deflection control circuit 130 through a corresponding amplifier, disposed for each electrode, of the DAC amplifier unit 136.

The stage position detector 139 emits a laser light to the mirror 210 on the XY stage 105, and receives a reflected light from the mirror 210. The stage position detector 139 measures the position of the XY stage 105, based on the principle of laser interferometry which uses information of the reflected light.

In the control computer 110, there are arranged a rasterization unit 50, a dose data generation unit 52, a beam-position deviation map generation unit 54, a position deviation correction unit 56, a detection unit 57, a specification unit 58, a defect correction unit 60, a finite dose determination unit 62, a dose-data-for-defect generation unit 64, an irradiation time calculation unit 66, a data processing unit 67, a NULL determination unit 68, and a writing control unit 74. Each of the “ . . . units” such as the rasterization unit 50, the dose data generation unit 52, the beam-position deviation map generation unit 54, the position deviation correction unit 56, the detection unit 57, the specification unit 58, the defect correction unit 60, the finite dose determination unit 62, the dose-data-for-defect generation unit 64, the irradiation time calculation unit 66, the data processing unit 67, the NULL determination unit 68, and the writing control unit 74 includes processing circuitry. The processing circuitry includes, for example, an electric circuit, computer, processor, circuit board, quantum circuit, or semiconductor device. Each “ . . . unit” may use common processing circuitry (the same processing circuitry), or different processing circuitry (separate processing circuitry). Information input/output to/from the rasterization unit 50, the dose data generation unit 52, the beam-position deviation map generation unit 54, the position deviation correction unit 56, the detection unit 57, the specification unit 58, the defect correction unit 60, the finite dose determination unit 62, the dose-data-for-defect generation unit 64, the irradiation time calculation unit 66, the data processing unit 67, the NULL determination unit 68, and the writing control unit 74, and information being operated are stored in the memory 112 each time.

Writing data is input from the outside of the writing apparatus 100, and stored in the storage device 140. The writing data generally defines information on a plurality of figure patterns to be written. Specifically, it defines a figure code, coordinates, size, etc. of each figure pattern.

FIG. 1 shows a configuration necessary for describing the first embodiment. Other configuration elements generally necessary for the writing apparatus 100 may also be included therein.

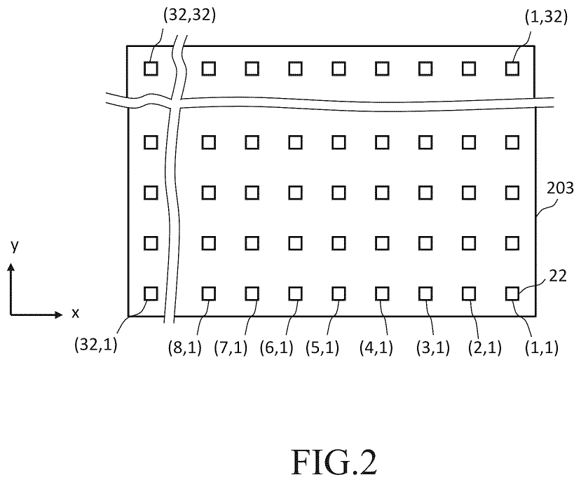

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 512×512, that is 512 (rows of holes arrayed in the y direction)×512 (columns of holes arrayed in the x direction), are formed. Each of the holes 22 is rectangular, including square, having the same dimension and shape as each other. Alternatively, each of the holes 22 may be a circle with the same diameter as each other. The shaping aperture array substrate 203 (beam forming mechanism) forms multiple beams 20. Specifically, the multiple beams 20 are formed by letting portions of an electron beam 200 individually pass through a corresponding one of a plurality of holes 22. The method of arranging the holes 22 is not limited to the case of FIG. 2 where the holes are arranged like a grid in the width and length directions. For example, with respect to the x-direction kth and (k+1)th rows which are arrayed in the length direction (in the y direction), each hole in the kth row and each hole in the (k+1)th row may be arranged mutually displaced in the width direction (in the x direction) by a dimension “a”. Similarly, with respect to the x-direction (k+1)th and (k+2)th rows which are arrayed in the length direction (in the y direction), each hole in the (k+1)th row and each hole in the (k+2)th row may be arranged mutually displaced in the width direction (in the x direction) by a dimension “b”.

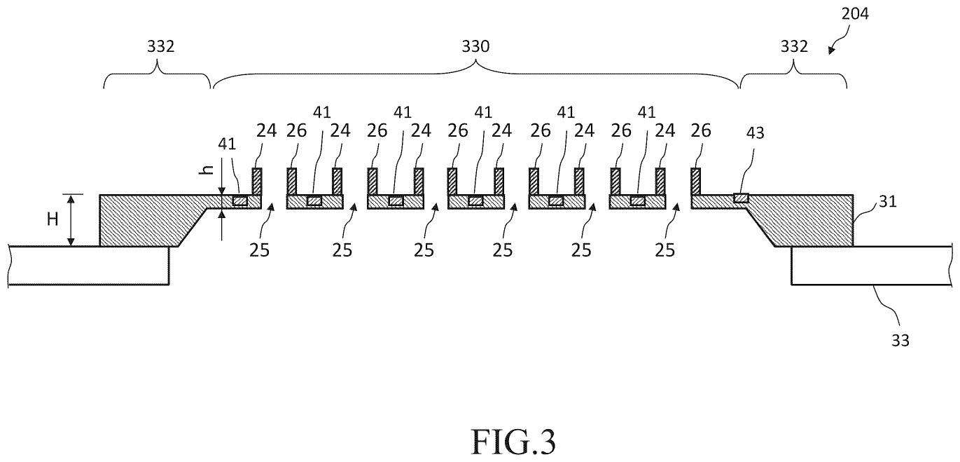

FIG. 3 is a sectional view showing a configuration of a blanking aperture array mechanism according to the first embodiment. With regard to the structure of the blanking aperture array mechanism 204, as shown in FIG. 3, a semiconductor substrate 31 made of silicon, etc. is placed on a support table 33. The central part of the substrate 31 is shaved, for example, from the back side and processed into a membrane region 330 (the first region) having a thin film thickness h. The periphery surrounding the membrane region 330 is an outer peripheral region 332 (the second region) having a thick film thickness H. The upper surface of the membrane region 330 and that of the outer peripheral region 332 are formed to be flush or substantially flush in height with each other. At the back side of the outer peripheral region 332, the substrate 31 is supported on the support table 33. The central part of the support table 33 is open, and the membrane region 330 is located at this opening region.

In the membrane region 330, passage holes 25 (openings) through each of which a corresponding one of the multiple beams 20 passes are formed at positions each corresponding to each hole 22 in the shaping aperture array substrate 203 shown in FIG. 2. In other words, in the membrane region 330 of the substrate 31, there are formed a plurality of passage holes 25, in an array state, through each of which a corresponding one of the multiple electron beams 20 passes. Further, in the membrane region 330 of the substrate 31, there are arranged a plurality of electrode pairs each composed of two electrodes being opposite to each other across a corresponding one of a plurality of passage holes 25. Specifically, in the membrane region 330, as shown in FIG. 3, each pair of a control electrode 24 and a counter electrode 26, (blanker: blanking deflector: first deflector), for blanking deflection is arranged close to a corresponding passage hole 25 in a manner such that the electrodes 24 and 26 are opposite to each other across the passage hole 25 concerned. Further, close to each passage hole 25 in the membrane region 330, inside the substrate 31, there is arranged a control circuit 41 (logic circuit) which applies a deflection voltage to the control electrode 24 for the passage hole 25 concerned. The counter electrode 26 for each beam is grounded.

In the control circuit 41, an amplifier (not shown) (an example of a switching circuit) is arranged. As an example of the amplifier, a CMOS (complementary MOS) inverter circuit is arranged. The CMOS inverter circuit is connected to a positive potential (Vdd: blanking potential: first potential) (e.g., 5 V) (the first potential) and to a ground potential (GND: the second potential). The output line (OUT) of the CMOS inverter circuit is connected to the control electrode 24. By contrast, the counter electrode 26 is applied with a ground potential. A plurality of control electrodes 24, each of which is applied with a blanking potential and a ground potential in a switchable manner, are arranged on the substrate 31 such that each control electrode 24 and the corresponding counter electrode 26 are opposite to each other across the passage hole 25 concerned in the plurality of passage holes 25.

As an input (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit becomes a positive potential (Vdd). Then, a corresponding one of the multiple beams 20 is deflected by an electric field due to a potential difference from the ground potential of the counter electrode 26, and controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding one of the multiple beams 20 is not deflected, and controlled to be in a beam ON condition by passing through the limiting aperture substrate 206.

A corresponding one of the multiple beams 20, passing through a corresponding passage hole, is deflected by a voltage independently applied to a pair of the control electrode 24 and the counter electrode 26. Blanking control is provided by this deflection. Specifically, a pair of the control electrode 24 and the counter electrode 26 individually provides blanking deflection of a corresponding beam of the multiple beams 20 by an electric potential switchable by the CMOS inverter circuit serving as a switching circuit corresponding to each pair. Thus, each of a plurality of blankers performs blanking deflection of a corresponding one of the multiple beams 20 having passed through a plurality of holes 22 (openings) in the shaping aperture array substrate 203.

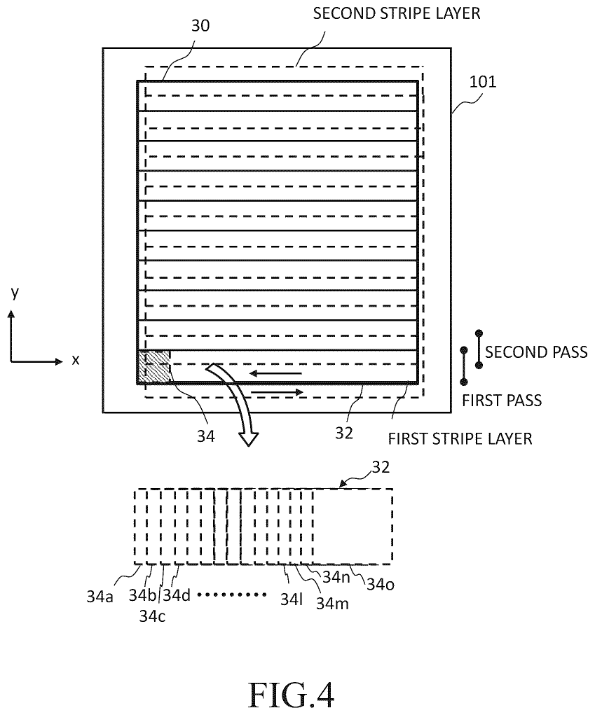

FIG. 4 is a conceptual diagram illustrating an example of a writing operation according to the first embodiment. As shown in FIG. 4, a writing region 30 (bold line) of the target object 101 is virtually divided, for example, by a predetermined width in the y direction into a plurality of stripe regions 32 in a strip form.

In the example of FIG. 4, there are configured a first stripe layer composed of a plurality of stripe regions 32 obtained by dividing the writing region 30, and a second stripe layer composed of a plurality of stripe regions 32 obtained by shifting (displacing) the first stripe layer in the y direction by the shift amount of ½ of the width of the stripe region 32. Thus, in the example of FIG. 4, two stipe layers of the first stripe layer and the second stripe layer are set. Therefore, by combining the first stripe layer and the second stripe layer, a plurality of stripe regions 32 are set with partially overlapped in the y direction with each other. FIG. 4 shows the case where the stripe regions 32 adjacent in the y direction to each other are mutually overlapped by half of each region. Further, it is preferable for the second stripe layer to set one surplus stripe region 32, in the −y direction, from the end of the writing region 30. Next, an example of the writing operation will be described.

First, the XY stage 105 is moved to make an adjustment such that the irradiation region 34 of the multiple beams 20 is located at the left end, or at a position further left than the left end, of the first stripe region 32 of the second stripe layer, and then writing of the first stripe region 32 of the second stripe layer is started. When the first stripe region 32 of the second stripe layer being written, the XY stage 105 is moved, for example, in the −x direction, so that the writing may relatively proceed in the x direction. The XY stage 105 is moved, for example, continuously at a constant speed. After writing the first stripe region 32 of the second stripe layer, the stage position is moved in the −y direction by the shift amount being ½ of the width of the stripe region 32.

Next, an adjustment is made so that the irradiation region 34 of the multiple beams 20 can be located at the right end, or at a position further right than the right end, of the first stripe region 32 of the first stripe layer. By moving the XY stage 105, for example, in the x direction, the writing relatively proceeds in the −x direction. Thereby, writing of the first stripe region 32 of the first stripe layer is carried out. After writing the first stripe region 32 of the first stripe layer, the second stripe region 32 of the second stripe layer is performed. Thus, by alternately writing the first stripe layer and the second stripe layer, it becomes possible to perform multiple writing at each position. Although, in the above, the case of performing writing while alternately changing the direction is described, it is not limited thereto. Respective stripe regions 32 may be written in the same direction.

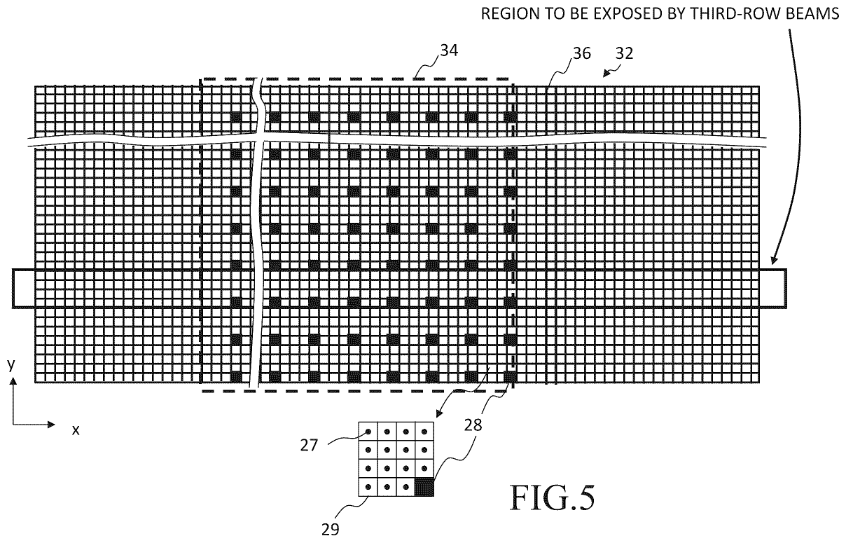

FIG. 5 is an illustration showing an example of an irradiation region of multiple beams and a pixel to be written (writing target pixel) according to the first embodiment. In FIG. 5, in the stripe region 32, there are set a plurality of control grids 27 (design grids) arranged in a grid form at the beam size pitch of the multiple beams 20 on the surface of the target object 101, for example. Preferably, the control grids 27 are arranged at a pitch of around 10 nm. The plurality of control grids 27 serve as design irradiation positions (irradiation positions in design) of the multiple beams 20. The arrangement pitch of the control grid 27 is not limited to the beam size, and may be any size that can be controlled as a deflection position of the deflector 209, regardless of the beam size. Then, a plurality of pixels 36 are set by virtually dividing into meshes, each centering on each control grid 27, by the same size as that of the arrangement pitch of the control grid 27. Each pixel 36 serves as an irradiation unit region per beam of the multiple beams. FIG. 5 shows the case where the writing region of the target object 101 is divided, for example, in the y direction, into a plurality of stripe regions 32 by the width size being substantially the same as the size of the irradiation region 34 (writing field) which can be irradiated by one irradiation with the multiple beams 20 (beam array). The x-direction size of the irradiation region 34 can be defined by the value obtained by multiplying the x-direction beam pitch (pitch between beams) of the multiple beams 20 by the number of x-direction beams. The y-direction size of the irradiation region 34 can be defined by the value obtained by multiplying the y-direction beam pitch of the multiple beams 20 by the number of y-direction beams. The width of the stripe region 32 is not limited to this. Preferably, the width of the stripe region 32 is n times (n being an integer of one or more) the size of the irradiation region 34. FIG. 5 shows the case where the multiple beams of 512×512 (rows×columns) are simplified to 8×8 (rows×columns). In the irradiation region 34, there are shown a plurality of pixels 28 (beam writing positions) which can be irradiated with one shot of the multiple beams 20. In other words, the pitch between adjacent pixels 28 is the pitch between beams of the multiple beams in design. In the example of FIG. 5, one sub-irradiation region 29 is a region surrounded by beam pitches. In the case of FIG. 5, each sub-irradiation region 29 is composed of 4×4 pixels.

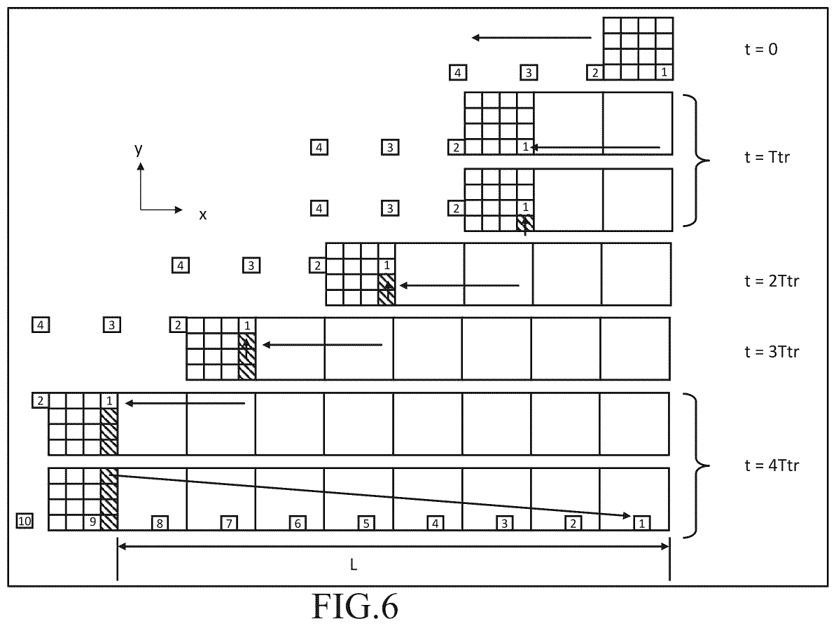

FIG. 6 is an illustration showing an example of a writing method of multiple beams according to the first embodiment. FIG. 6 shows a portion of the sub-irradiation region 29 to be written by each of beams at the coordinates (1, 3), (2, 3), (3, 3), . . . , (512, 3) of the y-direction k-th row in the multiple beams for writing the stripe region 32 shown in FIG. 5. In the example of FIG. 6, while the XY stage 105 moves the distance of eight beam pitches, four pixels are written (exposed), for example. In order that the relative position between the irradiation region 34 and the target object 101 may not deviate by the movement of the XY stage 105 while these four pixels are written (exposed), all of the multiple beams 20 are collectively deflected by the deflector 208. Thereby, the irradiation region 34 is made to follow the movement of the XY stage 105. In other words, tracking control is performed. The deflector 208, as a tracking deflector, performs a tracking deflection of the multiple beams 20 so that the irradiation region 34 of the multiple beams 20 may follow the movement of the stage. In the case of FIG. 6, one tracking cycle is executed by writing (exposing) four pixels during moving the distance of eight beam pitches.

Specifically, in each shot, beam irradiation is performed during a writing time (irradiation time or exposure time) corresponding to each control grid 27 within the maximum writing time having been set. Specifically, each control grid 27 is irradiated with a corresponding ON beam in the multiple beams 20. Then, at each completion of the shot cycle time Ttr obtained by adding a settling time of the DAC amplifier to the maximum writing time, the irradiation position of each beam is moved to the next shot position by a collective deflection by the deflector 209.

In the case of FIG. 6, when four shots have been completed, the DAC amplifier unit 134 resets a beam deflection for tracking control. Thereby, the tracking position is returned to the tracking start position where the tracking control was started.

Writing of the pixels in the first column from the right of each sub-irradiation region 29 has been completed. Therefore, after resetting the tracking, in a next tracking cycle, the deflector 209 first performs deflection to adjust (shift) the writing position of each corresponding beam to the control grid 27 of the pixel in the bottom row and the second column from the right of each sub-irradiation region 29. By repeating such an operation, all the pixels are written. When the sub-irradiation region 29 is composed of n×n pixels, each n pixels are written by different beams by n-time tracking operations. Thereby, all of the pixels in one region of n×n pixels are written. With respect also to other regions each composed of n×n pixels in the irradiation region of the multiple beams, the same operation is executed at the same time so as to perform writing similarly.

By the operation described above, as shown in the irradiation regions 34a to 340 in FIG. 4, writing processing proceeds while the irradiation region 34 shifts in the stripe region 32 by, for example, eight beam pitches being a stage movement amount of one tracking control.

Next, operations of the writing mechanism 150 of the writing apparatus 100 will be described. The electron beam 200 emitted from the electron gun 201 (emission source) illuminates the whole of the shaping aperture array substrate 203 by the illumination lens 202. A plurality of rectangular (including square) holes 22 (openings) have been formed in the shaping aperture array substrate 203. Then, the region including all of the plurality of holes 22 is irradiated with the electron beam 200. Portions of the electron beam 200 applied to the positions of the plurality of holes 22 individually pass through a corresponding hole of the plurality of holes 22 in the shaping aperture array substrate 203. Thereby, for example, a plurality of rectangular (including square) electron beams (multiple beams 20) are formed. The multiple beams 20 individually pass through corresponding blankers (the first deflector) of the blanking aperture array mechanism 204. Each blanker deflects (provides blanking deflection) the electron beam passing therethrough individually.

The multiple beams 20 having passed through the blanking aperture array mechanism 204 are reduced by the reducing lens 205, and travel toward the hole in the center of the limiting aperture substrate 206. Then, an electron beam in the multiple beams 20 which was deflected by the blanker of the blanking aperture array mechanism 204 deviates from the hole in the center of the limiting aperture substrate 206 and is blocked by the limiting aperture substrate 206. In contrast, an electron beam which was not deflected by the blanker of the blanking aperture array mechanism 204 passes through the hole in the center of the limiting aperture substrate 206 as shown in FIG. 1. Blanking control is provided by ON/OFF of the blanker so as to control ON/OFF of beams. Thus, the limiting aperture substrate 206 blocks each beam which was deflected to be in the OFF state by the blanker. Then, for each beam, one shot beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, respective beams having passed through the limiting aperture substrate 206, namely the whole of the multiple beams 20 having passed, are collectively deflected in the same direction by the deflectors 208 and 209 in order to irradiate respective beam irradiation positions on the target object 101. Ideally, the multiple beams 20 irradiating at a time are aligned at the pitch obtained by multiplying the arrangement pitch of the plurality of holes 22 in the shaping aperture array substrate 203 by a desired reduction ratio described above.

As described above, a defective beam may be generated in the multiple beams. As the defective beam, exemplified are an excessive dose defective beam which delivers an excessive dose irradiation since controlling the beam dose is disabled, and an insufficient dose defective beam which delivers an insufficient dose irradiation since controlling the beam dose is disabled. Excessive dose defective beams include ON defective beams which are “always ON”, and/or a portion of uncontrollable defective beams whose irradiation time is uncontrollable. Insufficient dose defective beams include OFF defective beams which are “always OFF”, and/or a remaining of uncontrollable defective beams.

If a target object is irradiated with a dose more excessive than planned, because of a defective beam, a problem occurs that a shape error of a pattern formed on the target object is generated. To solve this problem, defect correction is performed by cancelling off the excessive dose. According to the first embodiment, multiple writing of writing processing performed by a plurality of writing passes is executed. Then, the defect correction is done at another writing pass different from the writing pass applying a defective beam. Multiple beam writing proceeds, for example, while shifting (displacing) a rectangular region (an example of a unit region) irradiated with the multiple beams 20 in the writing region of the target object 101. The rectangular region (beam array region), here, is the irradiation region 34 of the multiple beams which is configured by combining each sub-irradiation region 29 (sub region) surrounded by a target beam and a plurality of beams adjacent to the target beam, with respect to each beam of the multiple beams. The unit region is not limited to a quadrangle, and may be other regions in accordance with the arrangement shape of the multiple beams.

In the case of FIG. 4, since the irradiation region 34 shifts by the distance of, for example, eight beam pitches per tracking cycle, the rectangular regions irradiated with the multiple beams 20 overlap with each other while being shifted by eight beam pitches in the stripe region 32. For example, in the rectangular region corresponding to the irradiation region 34a, the pixels in the first column from the right of each sub-irradiation region 29 are to be irradiated. For example, in the rectangular region corresponding to the irradiation region 34b, the pixels in the second column from the right of each sub-irradiation region 29 are to be irradiated.

For example, in the rectangular region corresponding to the irradiation region 34c, the pixels in the third column from the right of each sub-irradiation region 29 are to be irradiated. For example, in the rectangular region corresponding to the irradiation region 34d, the pixels in the fourth column from the right of each sub-irradiation region 29 are to be irradiated. Also, in the subsequent rectangular regions, pixels to be irradiated (irradiation target pixels) shift similarly. In such a case, with regard to a rectangular region where no pattern exists in the irradiation target region, writing processing for that rectangular region is preferably skipped in order to reduce the writing time.

In the case of skipping the writing processing for the rectangular region, during the operation of skipping, the whole of the multiple beams 20 including a defective beam 11 can be blocked by the limiting aperture substrate 206 by collectively deflecting the entire multiple beams 20 by the collective blanking deflector 212.

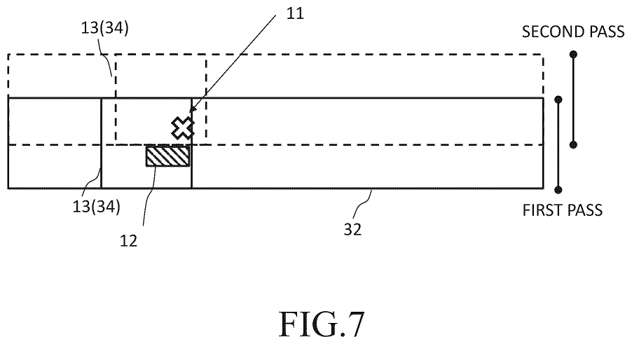

FIG. 7 is an illustration showing an example of “with or without” a pattern at each writing pass according to the first embodiment. In FIG. 7, a pattern 12 is arranged in a rectangular region 13 where a tracking control is performed at the first writing pass (first pass). The rectangular region 13 includes the position irradiated with the defective beam 11 in the second writing pass (second pass). The position irradiated with the defective beam 11 in the first pass is not shown in FIG. 7.

When dose data for irradiation to the rectangular region 13 of the first pass is generated, the data generation is carried out on the premise of correcting a defect due to an excessive dose by irradiation of the defective beam 11 emitted in the second writing pass. The position irradiated with the defective beam 11 at the second pass is included in the rectangular region 13 for performing a tracking control. Here, there may be a case where the rectangular region 13 including the position irradiated with the defective beam 11 at the second pass does not have any pattern as shown in FIG. 7. Thus, when correction of an excessive dose due to a defective beam is performed across the writing passes of multiple writing, the rectangular region 13 including a position irradiated with a defective beam at a certain writing pass may possibly be a region without a pattern. With regard to dose data, it is generated independently among writing passes. In that case, if the writing processing for the rectangular region 13 without a pattern is skipped at the second writing pass, irradiation of the defective beam 11 is not performed, thereby breaking the premise of correction at the first writing pass. Consequently, a problem occurs in that a defect correction being unnecessary is carried out.

In contrast, there is a case where the rectangular region 13 of the second pass may include a position irradiated with a defective beam in the first pass. When dose data for irradiation to the rectangular region 13 of the second pass is generated, the data generation is carried out on the premise of correcting a defect due to an excessive dose by irradiation of a defective beam emitted in the first pass. However, there may be a case where the rectangular region including the position irradiated with the defective beam in the first pass does not have any pattern. If the writing processing for the rectangular region without a pattern is skipped at the first writing pass, irradiation of the defective beam is not performed, thereby breaking the premise of correction at the second writing pass. Consequently, a problem occurs in that a defect correction being unnecessary is carried out.

Then, according to the first embodiment, if a pixel, where a designed nonzero value (finite value) is defined, exists around the position irradiated with a defective beam, it is controlled not dare to perform skipping even if the rectangular region 13 for a tracking control has no pattern.

For example, when a defective beam is emitted in the writing processing of the first pass, there is a case where the rectangular region 13, including the position irradiated with a defective beam in the first pass, to be irradiated in the second pass is a region without a pattern. If, from the first, there is no designed pattern around a defective beam, a pattern shape error resulting from a defective beam does not occur. In such a case, since the defective beam can be ignored, it is acceptable to skip the writing processing.

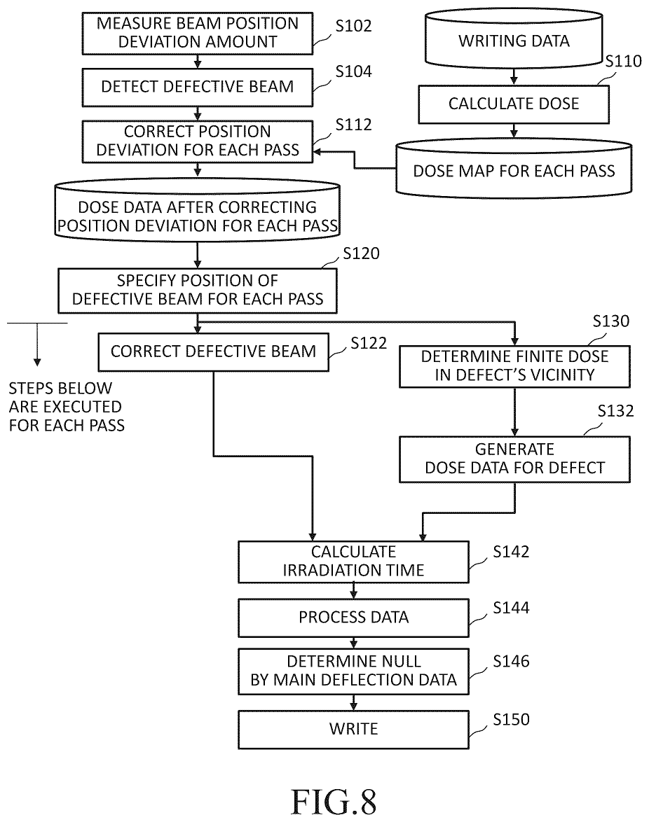

FIG. 8 is a flowchart showing an example of main steps of a writing method according to the first embodiment. In FIG. 8, the writing method of the first embodiment executes a series of steps: a beam-position deviation amount measurement step (S102), a defective beam detection step (S104), a dose calculation step (S110), a position deviation correction step (S112) for each pass, a defective beam position specification step (S120) for each pass, a defective beam correction step (S122), a defect's vicinity finite dose determination step (S130), a dose-data-for-defect generation step (S132), an irradiation time calculation step (S142), a data processing step (S144), a main deflection data NULL determination step (S146), and a writing step (S150).

Each of the defective beam correction step (S122), the defect's vicinity finite dose determination step (S130), the dose-data-for-defect generation step (S132), the irradiation time calculation step (S142), the data processing step (S144), the main deflection data NULL determination step (S146), and the writing step (S150) is carried out for each writing pass.

In the beam-position deviation amount measurement step (S102), the writing apparatus 100 measures the amount of position deviation of each beam irradiation position of multiple beams on the target object 101 surface, deviating from each corresponding control grid 27.

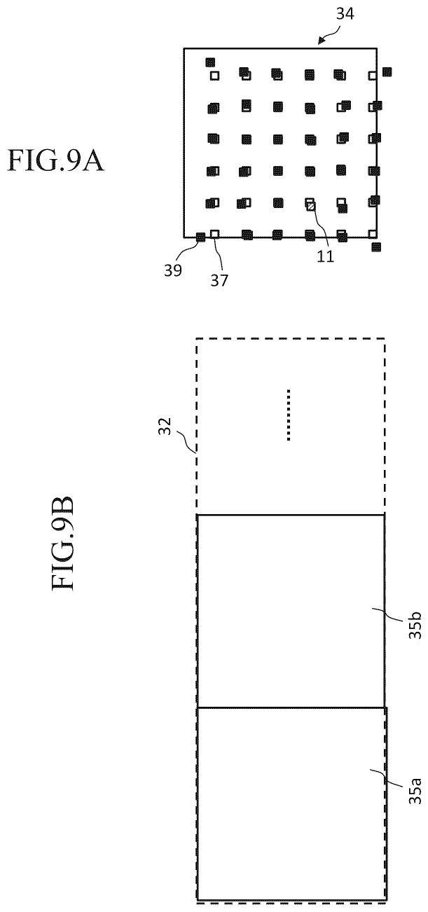

FIGS. 9A and 9B are illustrations each showing a beam position deviation and a position deviation periodicity according to the first embodiment. With regard to the multiple beams 20, as shown in FIG. 9A, distortion occurs in an exposure field due to the characteristics of the optical system, and therefore, because of the distortion and the like, an actual irradiation position 39 of each beam is deviated from an irradiation position 37 being an irradiation position of an ideal grid. Then, according to the first embodiment, the amount of position deviation of the actual irradiation position 39 of each beam is measured. Specifically, an evaluation substrate coated with resist is irradiated with the multiple beams 20, and is developed in order to generate a resist pattern. Then, the position of the generated resist pattern is measured by a position measuring instrument, thereby measuring a position deviation amount of each beam. If it is difficult to measure the size of the resist pattern at the irradiation position of each beam by a position measuring instrument since the shot size of the beam concerned is small, a figure pattern (e.g., rectangular pattern) of a measurable size by the position measuring instrument is to be written. Then, edge positions of the both sides of the figure pattern (resist pattern) are measured to measure a position deviation amount of a target beam based on a difference between the intermediate position of the both edges and the intermediate position of a design figure pattern (figure pattern in design). Obtained position deviation amount data on each beam irradiation position is input to the writing apparatus 100, and stored in the storage device 144. Further, in the multiple beam writing, since writing proceeds while shifting the irradiation region 34 in the stripe region 32, the position of the irradiation region 34 moves one by one, such as from the irradiation region 34a to 340, during writing of the stripe region 32 as shown in the lower part of FIG. 4 according to the writing sequence explained in FIG. 6, for example. Then, periodicity occurs in position deviation of each beam every time the irradiation region 34 is moved. Alternatively, if in the case of the writing sequence where each beam irradiates all of the pixels 36 in the sub-irradiation region 29 corresponding to the beam concerned, as shown in FIG. 9B, periodicity occurs in position deviation of each beam at least in each unit region 35 (35a, 35b, . . . ) of the same size as the irradiation region 34. Therefore, when the position deviation amount of each beam for one irradiation region 34 in the beam array is measured, the measurement result can also be used for other regions. In other words, it is sufficient to measure a position deviation amount at each pixel 36 in the sub-irradiation region 29 corresponding to each beam.

The beam-position deviation map generation unit 54 generates a beam-position deviation amount map (1) which defines a position deviation amount of each beam of each pixel 36 in a beam array unit, in other words, in one quadrangular unit region 35 on the surface of the target object corresponding to the irradiation region 34. Specifically, the beam-position deviation map generation unit 54 reads position deviation amount data on the irradiation position of each beam from the storage device 144, and generates the beam-position deviation amount map (1) by using the data as a map value. Which beam irradiates the control grid 27 of each pixel 36 in one quadrangular unit region 35 on the surface corresponding to the irradiation region 34 of the whole of the multiple beams 20 is determined based on the writing sequence as described with reference to FIG. 6, for example. Therefore, the beam-position deviation map generation unit 54 specifies, per control grid 27 of each pixel 36 in one unit region 35, a beam to irradiate the control grid 27 concerned according to the writing sequence, and calculates a position deviation amount of the beam concerned. The generated beam-position deviation amount map (1) is stored in the storage device 144.

In the defective beam detection step (S104), the detection unit 57 detects a defective beam in the multiple beams 20. The ON defective beam being “always ON” performs all the time an irradiation of the maximum irradiation time, which is maximum in one shot, regardless of the control dose. Alternatively, furthermore, it continues the irradiation also during moving from one pixel to another. The OFF defective beam being “always OFF” is all the time “beam OFF” regardless of the control dose. Specifically, under the control of the writing control unit 74, the writing mechanism 150 controls each of the multiple beams 20 to be “beam ON” one by one by the blanking aperture array mechanism 204, and the other beams, except for the “ON” beams, to be “OFF”. In such a state, if there is a beam whose current is not detected by the Faraday cup 106, it is detected as an OFF defective beam. Then, the control is switched from this state to a state in which a target beam to be detected is an “OFF” beam. In that case, if there is a beam whose current is detected by the Faraday cup 106 all the time, in spite of having been switched from an “ON” beam to an “OFF” beam to be detected, it is detected as an ON defective beam. If there is a beam whose current is detected by the Faraday cup 106 during a predetermined period, after having been switched from an “ON” beam to an “OFF” beam to be detected, it is detected as an uncontrollable defective beam. By checking each of the multiple beams 20 in order by the same method, it is possible to detect whether there is a defective beam or not, what kind of a defective beam is, and where a defective beam is located. Although the case of also detecting a defective beam other than an ON defective beam is here described, it is also acceptable to detect only an ON defective beam being “always ON”. Information on a detected defective beam is stored in the storage device 144.

In the dose calculation step (S110), the dose data generation unit 52 (dose calculation unit) generates, for each of a plurality of processing regions obtained by dividing the writing region on the surface of the target object 101, dose data which defines an individual dose of each position in the processing region concerned. Specifically, it operates as follows: First, the rasterization unit 50 reads writing data from the storage device 140, and calculates, for each pixel 36, a pattern area density ρ′ in the pixel 36 concerned. This processing is performed for each stripe region 32, for example.

Next, the dose data generation unit 52, first, virtually divides the writing region (e.g., in this case, stripe region 32) into a plurality of proximity mesh regions (mesh regions for proximity effect correction calculation) by a predetermined size. The size of the proximity mesh region is preferably set to be about 1/10 of the influence range of the proximity effect, such as about 1 μm. The dose data generation unit 52 reads writing data from the storage device 140, and calculates, for each proximity mesh region, a pattern area density ρ of a pattern arranged in the proximity mesh region concerned.

Next, the dose data generation unit 52 calculates, for each proximity mesh region, a proximity effect correction irradiation coefficient Dp(x) (correction dose) for correcting a proximity effect. An unknown proximity effect correction irradiation coefficient Dp(x) can be defined by a threshold value model for proximity-effect correction, which is the same as the one used in a conventional method, where a backscatter coefficient η, a dose threshold value Dth of a threshold value model, a pattern area density ρ, and a distribution function g(x) are used.

Next, the dose data generation unit 52 calculates, for each pixel 36, an incident dose D(x) (amount of dose) with which the pixel 36 concerned is irradiated. The incident dose D(x) can be calculated, for example, by multiplying a preset base dose Dbase by a proximity effect correction irradiation coefficient Dp and a pattern area density ρ′. The base dose Dbase can be defined by Dth/(½+η), for example. Thereby, it is possible to obtain an originally desired incident dose D(x), for which a proximity effect has been corrected, based on layout of a plurality of figure patterns defined by the writing data.

The dose data generation unit 52 performs the processing described above, for each processing region obtained by dividing the stripe region 32. As the processing region, for example, the quadrangular unit region 35 of the same size as the irradiation region 34 is used. The dose data generation unit 52 generates a dose map which defines, per processing region unit, an incident dose D(x) for each pixel 36. The incident dose D(x) for each pixel 36 is a designed planned incident dose D(x) to be applied to the control grid 27 of the pixel 36 concerned. The generated dose map is stored in the storage device 144, for example.

In the position deviation correction step (S112) for each pass, the position deviation correction unit 56 generates, for each writing pass, a dose map in which each position deviation of each irradiation position of the multiple beams 20 has been corrected.

First, the dose of each pixel is defined for each writing pass. Specifically, it operates as follows: The position deviation correction unit 56 reads a dose map from the storage device 144, and calculates the dose for each writing pass by dividing a dose defined for each pixel by the number of writing passes, for example. Next, position deviation of a beam to be applied to each pixel is corrected for each writing pass. Which beam irradiates which pixel, for each pass, is determined based on the writing sequence.

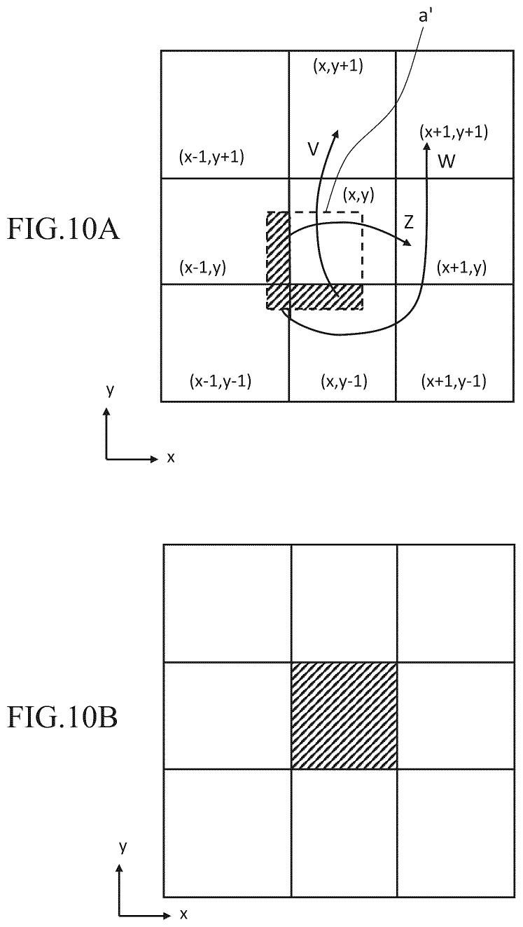

FIGS. 10A and 10B are illustrations showing an example of a method for correcting a position deviation according to the first embodiment. FIG. 10A shows the case where the position of a beam “a′” irradiating the pixel at coordinates (x, y) deviates in the −x and −y directions. In order to correct the deviated position of the pattern formed by the beam “a′” with such a position deviation to the position corresponding to the pixel at coordinates (x, y) as shown in FIG. 10B, correction can be accomplished by distributing (for sharing) the dose corresponding to the deviated position to pixels located opposite to the direction of peripheral deviated pixels. In the example of FIG. 10A, the dose corresponding to the position deviated to the pixel at coordinates (x, y−1) should be distributed to the pixel at coordinates (x, y+1). The dose corresponding to the position deviated to the pixel at coordinates (x−1, y) should be distributed to the pixel at coordinates (x+1, y). The dose corresponding to the position deviated to the pixel at coordinates (x−1, y−1) should be distributed to the pixel at coordinates (x+1, y+1).

According to the first embodiment, a position-deviation-correction distribution amount for distributing a dose to a beam for at least one of surrounding pixels is calculated in proportion to a beam position deviation amount. The position deviation correction data generation unit 52 calculates a modulation rate of a beam to the pixel concerned, and a modulation rate of a beam to at least one of peripheral pixels surrounding the pixel concerned, in proportion to a ratio of the area deviated due to the positional deviation of the beam to the pixel concerned. Specifically, for each of peripheral pixels where a portion of a beam is overlapped because the beam has deviated from the pixel concerned, a ratio is calculated by dividing the deviated area (area of beam overlapping portion) by the beam area, where the ratio is calculated as a distribution amount (beam modulation rate) distributed to a pixel located opposite, with respect to the pixel concerned, to the pixel of the overlapped beam.

In the case of FIG. 10A, the area ratio of the portion deviated to the pixel at coordinates (x, y−1) can be calculated by (“x direction beam size”−“−x direction deviation amount”)×“y direction deviation amount”/(“x direction beam size”×“y direction beam size”). Therefore, a distribution amount (beam modulation rate) V to be distributed for correction to the pixel at coordinates (x, y+1) can be calculated by (“x direction beam size”−“−x direction deviation amount”)×“y direction deviation amount”/(“x direction beam size”×“y direction beam size”).

Also, in the case of FIG. 10A, the area ratio of the portion deviated to the pixel at coordinates (x−1, y−1) can be calculated by “−x direction deviation amount”×“−y direction deviation amount”/(“x direction beam size”×“y direction beam size”). Therefore, a distribution amount (beam modulation rate) W to be distributed for correction to the pixel at coordinates (x+1, y+1) can be calculated by “−x direction deviation amount”×“−y direction deviation amount”/(“x direction beam size”×“y direction beam size”).

Also, in the case of FIG. 10A, the area ratio of the portion deviated to the pixel at coordinates (x−1, y) can be calculated by “−x direction deviation amount”×(“y direction beam size”−“−y direction deviation amount”)/(“x direction beam size”×“y direction beam size”). Therefore, a distribution amount (beam modulation rate) Z to be distributed for correction to the pixel at coordinates (x+1, y) can be calculated by “−x direction deviation amount”×(“y direction beam size”−“−y direction deviation amount)”/(“x direction beam size”×“y direction beam size”).

Consequently, a modulation rate U of the beam irradiating the pixel at coordinates (x, y), which remains without being distributed, can be calculated by 1−V−W−Z.

In this way, for each beam array unit, that is, for each pixel 36 in one quadrangular unit region 35 corresponding to the irradiation region 34 on the target object surface, the modulation rate of the beam to the pixel concerned, and the modulation rate of the beam to at least one peripheral pixel serving as a distribution destination are calculated.

The position deviation correction unit 56 calculates, for each writing pass and for each pixel 36, a value by multiplying the dose defined for the pixel concerned by the modulation rate of the beam to the pixel concerned. Further, the position deviation correction unit 56 calculates, for each writing pass and for each pixel 36, a value by multiplying the dose defined for the pixel concerned by the modulation rate of the beam to at least one peripheral pixel serving as a distribution destination. Then, the calculated value is distributed to the pixel at the distribution destination. The position deviation correction unit 56 calculates, for each writing pass and for each pixel 36, a dose by adding a value, which is obtained by multiplying the dose defined for the pixel concerned by the modulation rate of the beam to the pixel concerned, and a value distributed from the other pixel. Thereby, it is possible to generate a dose map for each writing pass where position deviation has been corrected, in other words, a dose map for each pass after position deviation having been corrected. The generated dose map for each pass after the position deviation having been corrected is stored in the storage device 144.

In the defective beam position specification step (S120) for each pass, the specification unit 55 specifies, for each writing pass, a pixel irradiated with an excessive dose defective beam including an “always ON” defective beam, with respect to each pixel 36 in each beam array unit, that is, with respect to each pixel 36 in one quadrangular unit region 35 corresponding to the irradiation region 34 on the target object surface. Which beam irradiates the control grid 27 of each pixel 36 in the quadrangular unit region 35 is determined based on the writing sequence as described above.

In the defective beam correction step (S122), the defect correction unit 60 performs correction for each writing pass so that an excessive dose having become excessive due to that a defective beam has been emitted in the other writing pass may be reduced.

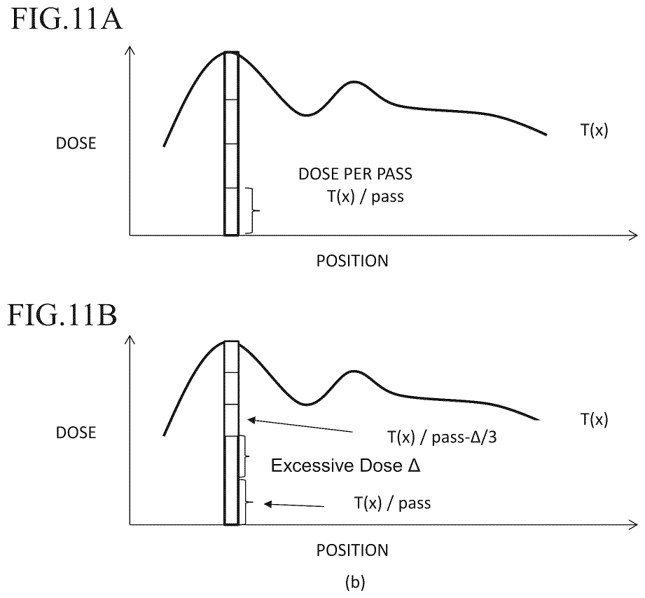

FIGS. 11A and 11B are illustrations showing an example of correction of a defective beam according to the first embodiment. FIG. 11A shows the case of performing multiple writing of four passes (multiplicity=4). In such a case, with regard to a pixel which is not irradiated with a defective beam, the dose in each writing pass is for example defined to be a value T(x)/pass obtained by dividing the dose T(x) applied to each pixel by the number of writing passes, that is “pass” (in this case, 4). However, with regard to a pixel irradiated with a defective beam, if nothing is done, it becomes an excessive dose. Since the dose in the writing pass applying a defective beam is uncontrollable, correction to obtain a dose by deducting an excessive dose Δ is performed in the other writing pass. In the example of FIG. 11B, a defective beam is emitted in one of the four writing passes. Then, first, the excessive dose Δ exceeding T(x)/pass is calculated. Next, with respect to the dose of each of the remaining three writing passes applying normal beams, correction to obtain a dose by deducting Δ/3 from each dose T(x)/pass is performed.

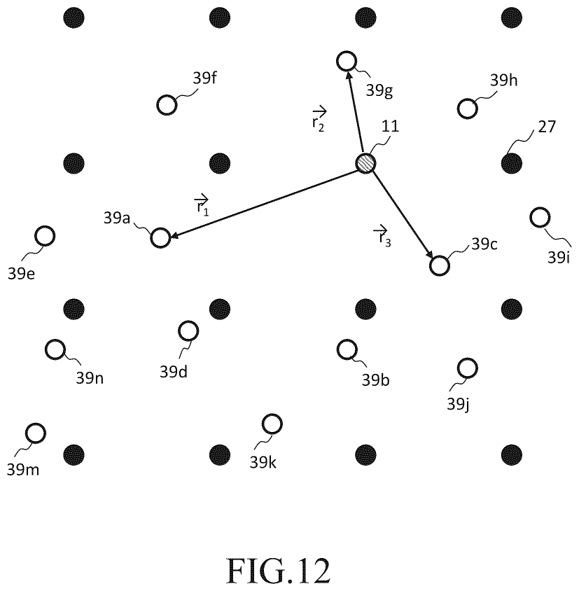

FIG. 12 is an illustration showing another example of correction of a defective beam according to the first embodiment. There is a case where a design dose at a position irradiated with a defective beam may be smaller than an excessive dose Δ. In that case, it is difficult to correct the excessive dose Δ by using only the pixel concerned. Then, the excessive dose Δ or an excessive dose which still remains because of not being able to be thoroughly corrected) at the pixel irradiated with the defective beam is distributed to peripheral beams. The defect correction unit 60 performs correction, for each writing pass, by distributing an excessive dose, which became excessive due to irradiation of a defective beam at a writing pass other than the writing pass concerned, to peripheral beams. As shown in FIG. 12, an excessive dose which still remains because of not being able to be thoroughly corrected is distributed to, for example, three irradiation positions 39a, 39c, and 39g located in the surrounding area of the irradiation position of the defective beam 11. In that case, each distribution dose to be distributed is calculated such that the center of gravity of the each distribution dose is at the irradiation position of the defective beam 11. Correction of the defective beam can be performed by deducting the calculated distribution dose from the dose of the beam at the irradiation position concerned.

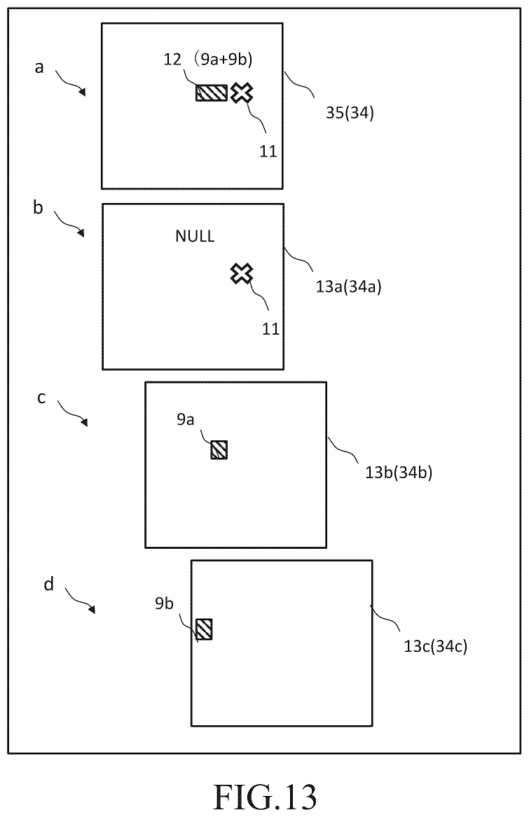

FIG. 13 is an illustration showing an example of “with or without” (existence or nonexistence) of a pattern in a processing region and that in each main deflection region according to a comparative example of the first embodiment. The section “a” of FIG. 13 shows “with or without” a pattern in the processing region of one of a plurality of writing passes of multiple writing. Here, the quadrangular unit region 35 is used as the processing region. In the example of the section “a” of FIG. 13, the pattern 12 in design is arranged in the quadrangular unit region 35. With respect to the writing pass concerned, the defective beam 11 is applied to the vicinity of the pattern 12. When the quadrangular unit region 35 is written, for each tracking control, the rectangular region 13 used as the main deflection region is set as described above.

In the section “b” of FIG. 13, a rectangular region 13a used as the main deflection region of the first tracking control is shown, for example. In the rectangular region 13a, pixels in the first pixel column from the right in each sub-irradiation region 29 are to be written (writing target), for example. The example of the section “b” of FIG. 13 shows the case where the defective beam 11 is a pixel to be written.

In the section “c” of FIG. 13, a rectangular region 13b used as the main deflection region of the second tracking control is shown, for example. In the rectangular region 13b, pixels in the second pixel column from the right in each sub-irradiation region 29 are to be written, for example. The example of the section “c” of FIG. 13 shows the case where a partial pattern 9a being a part of the pattern 12 is a pixel to be written.

In the section “d” of FIG. 13, a rectangular region 13c used as the main deflection region of the third tracking control is shown, for example. In the rectangular region 13c, pixels in the third pixel column from the right in each sub-irradiation region 29 are to be written, for example. The example of the section “d” of FIG. 13 shows the case where a partial pattern 9b being another part of the pattern 12 is a pixel to be written.

In the main deflection regions described above, no pattern is arranged in the rectangular region 13a. Therefore, the writing processing for the rectangular region 13a is skipped. In that case, since the defective beam 11 is not emitted, if defect correction is performed in the other writing pass, it becomes an unnecessary correction. Then, according to the first embodiment, controlling is performed such that the writing processing for the rectangular region 13a is not skipped under certain conditions.

In the defect's vicinity finite dose determination step (S130), the finite dose determination unit 62 (dose determination unit) determines, for each writing pass and for each processing region, whether the position where the dose of a nonzero value (finite value) is defined exists in the vicinal region including a defect position to be irradiated with a defective beam whose dose is excessive in the multiple beams 20.

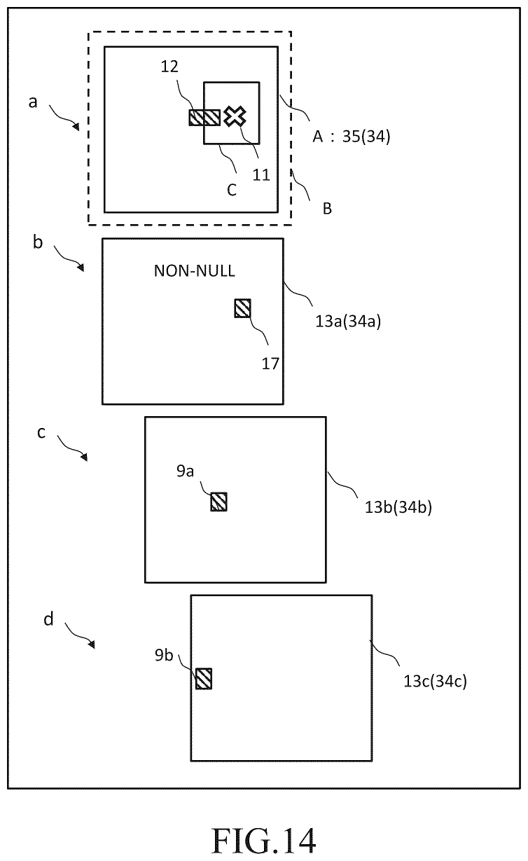

FIG. 14 is an illustration showing an example of “with or without” a pattern in a processing region and that in each main deflection region according to the first embodiment. The section “a” of FIG. 14 shows “with or without” a pattern in the processing region A of one of a plurality of writing passes of multiple writing. Here, the quadrangular unit region 35 is used as the processing region A. In the case of the section “a” of FIG. 14, similarly to the section “a” of FIG. 13, the pattern 12 in design is arranged in the quadrangular unit region 35. In the writing pass concerned, the defective beam 11 is applied to the vicinity of the pattern 12. Then, the finite dose determination unit 62 determines whether the position (pixel) where a dose of a nonzero value (finite value) is defined exists in the vicinal region C including a defect position (defective pixel) to be irradiated with the defective beam 11. As the vicinal region C, it is preferable to assume a correction region for correcting position deviation of the pixel to be irradiated with a defective beam. For example, a pixel region within the range of a radius of several pixels centering on the pixel to be irradiated with a defective beam is preferably assumed. Alternatively, a pixel region within the range of a radius of 1 to 2 beam size pitches centering on the pixel to be irradiated with a defective beam is preferably assumed. Although the rectangular region is here described as the vicinal region C, it is not limited thereto. For example, a circular region is also preferable. Further, a margin region B for considering a defective beam in the processing region adjacent to the circumference of the processing region A is set. Preferably, the margin width is set at several pixels to 1 to 2 beam pitches, for example.

The finite dose determination unit 62 determines whether the defective beam 11 exists in the processing region A and whether a pixel where a dose of a designed nonzero value (finite value) is defined exists in the vicinal region C. That case is on the premise that the pixel, where the dose of the nonzero value (finite value) is defined in the vicinal region C, does not exceed the margin region B. In the case of the section “a” of FIG. 14, since the defective beam 11 is in the processing region A, and a part of the pattern 12 is arranged in the vicinal region C, the finite dose determination unit 62 determines that the pixel where a dose of a designed nonzero value (finite value) is defined exists in the vicinal region C. Since the pixel where the dose of the nonzero value (finite value) in the vicinal region C does not exceed the margin region B, the premise has been satisfied.

Therefore, the finite dose determination unit 62 determines that there is a pixel where a dose of a designed nonzero value (finite value) is defined. As the dose of each pixel, values defined in the dose map stored in the storage device 144 is used. Preferably, a dose map after correction of position deviation of each pass is used as the dose map.

In the dose-data-for-defect generation step (S132), when the dose of a nonzero value (finite value) is defined in the vicinal region C, the dose-data-for-defect generation unit 64 (dose-data-for-defect-position generation unit) generates dose-data-for-defect defining a dose for a defect at the defect position. In the case of the section “a” of FIG. 14, the dose-data-for-defect is generated at the position irradiated with the defective beam 11. As the dose for a defect, the maximum dose at each writing pass is set, for example. As the maximum dose at each writing pass, the maximum dose of each pixel defined in the dose map (dose map after correction of position deviation of each pass) may be used.

In the irradiation time calculation step (S142), the irradiation time calculation unit 66 calculates an irradiation time t corresponding to the dose of each pixel. The irradiation time t can be obtained by dividing the dose D by a current density J. The irradiation time t of each pixel 36 (control grid 27) is calculated as a value within the maximum irradiation time Tₜᵣ which is the maximum for irradiation with one shot of the multiple beams 20. The irradiation time t of each pixel 36 (control grid 27) is converted to gray scale value data of 0 to 1023 gray scale levels in which the maximum irradiation time Tₜᵣ is, for example, 1023 gray scale levels (10 bits). The gray scaled irradiation time data is stored in the storage device 142.

In the data processing step (S144), the data processing unit 67 rearranges, at each writing pass, irradiation time data for each pixel in the order of main deflection region and in the order of shot. The rectangular region 13 serving as the main deflection region is set for each tracking control of tracking deflection. The case of arranging the example of the section “a” of FIG. 14 in order of main deflection region will be partially described. In the section “b” of FIG. 14, the rectangular region 13a used as the main deflection region of the first tracking control is shown, for example. In the rectangular region 13a, pixels in the first pixel column from the right in each sub-irradiation region 29 are writing targets, for example. The section “b” of FIG. 14 shows the case where the defective beam 11 is a target pixel. If dose-data-for-defect is defined for the position of the defective beam 11, it becomes the same state as that in which the pattern 17 for defect is defined as shown in the section “b” of FIG. 14. In the section “c” of FIG. 14, similarly to the section “c” of FIG. 13, the rectangular region 13b used as the main deflection region of the second tracking control is shown, for example. In the rectangular region 13b, pixels in the second pixel column from the right in each sub-irradiation region 29 are to be written, for example. The example of the section “c” of FIG. 14, similarly to the section “c” of FIG. 13, shows the case where a partial pattern 9a being a part of the pattern 12 is a pixel to be written. In the section “d” of FIG. 14, similarly to the section “d” of FIG. 13, a rectangular region 13c used as the main deflection region of the third tracking control is shown, for example. In the rectangular region 13c, pixels in the third pixel column from the right in each sub-irradiation region 29 are to be written, for example. The example of the section “d” of FIG. 14, similarly to the section “d” of FIG. 13, shows the case where a partial pattern 9b being another part of the pattern 12 is a pixel to be written.

In the main deflection regions described above, with respect to the rectangular region 13a, the state has been changed from the state in which a pattern is not arranged as shown in the section “b” of FIG. 13 to the state in which the pattern 17 for defect is arranged as shown in the section “b” of FIG. 14.

Thus, shot data varies for each main deflection region.

In the main deflection data NULL determination step (S146), for each rectangular region 13 on the target object 101 surface where the irradiation region 34 of the multiple beams 20 is set, the NULL determination unit 68 (pattern existence determination unit) performs a determination of whether a pattern to be arranged in the rectangular region 13 concerned exists, using dose data of each position to be irradiated in the rectangular region 13 concerned. When a pattern is present in the rectangular region 13 concerned, the main deflection data is generated for the rectangular region 13 concerned. Irradiation time data of the rectangular region 13 serving as a main deflection region is used as main deflection data. It is determined to be NULL (without a pattern) when in the state of there being no main deflection data, i.e., the state of there being no pattern. Thus, the NULL determination unit 68 determines NULL (without a pattern) by the main deflection data. In the sections from “b” to “d” in FIG. 14, each of them is determined to be non-NULL (with pattern). Particularly, in the rectangular region 13a irradiated with the defective beam 11, even in the case of there being no design pattern, since the dose-data-for-defect is defined, no writing processing is skipped.

In the writing step (S150), the writing mechanism 150 skips the writing processing for the rectangular region 13 in which no pattern was determined to exist, and moves the rectangular region 13 in which the writing processing is to be performed to the next rectangular region 13 in which a pattern was determined to exist, so as to write a pattern on the target object 101 using the multiple beams 20 while performing correction of an excessive dose, which is resulting from the defective beam 11 at any writing pass, at other writing pass in a plurality of writing passes of multiple writing. In the case of FIG. 14, for example, even when defect correction is performed in the first writing pass on the premise that the defective beam 11 is emitted in the second writing pass, irradiation of the defective beam 11 is performed without being skipped in the second writing pass. Therefore, the defect correction at the first writing pass can function effectively. Similarly, for example, even when defect correction is performed in the second writing pass on the premise that the defective beam 11 is emitted in the first writing pass, irradiation of the defective beam 11 is performed without being skipped in the first writing pass. Therefore, the defect correction at the second writing pass can function effectively.

As described above, according to the first embodiment, it is possible to avoid unnecessary correction of a defect in the case of correcting, across the writing passes of multiple writing, an excessive dose caused by the defective beam 11.

### Second Embodiment

According to the first embodiment described above, by generating dose-data-for-defect for the irradiation position of a defective beam, it is made to determine that there is a pattern even in the rectangular region 13 without a pattern as explained in the main deflection data NULL determination step (S146). Now, a second embodiment describes other configurations. The configuration of the writing apparatus in the second embodiment is the same as that of FIG. 1. The flowchart showing main steps of the writing method of the second embodiment is the same as that of FIG. 8. The contents of the second embodiment are the same as those of the first embodiment except for what is particularly described below.

In the main deflection data NULL determination step (S146) of the second embodiment, the NULL determination unit 68 (pattern existence determination unit) determines that a pattern to be arranged in each rectangular region 13 exists. In other words, the NULL determination unit 68 (pattern existence determination unit) determines, in each rectangular region 13, to be non-NULL (with pattern) regardless of “with or without” a pattern. Other respects are the same as those of the first embodiment.

In the second embodiment, the defect's vicinity finite dose determination step (S130) and the dose-data-for-defect generation step (S132) may be omitted. In that case, the finite dose determination unit 62 and the dose-data-for-defect generation unit 64 may be omitted.

Thereby, although existence of the rectangular region 13 to be skipped is disappeared, it becomes possible to avoid the state where no defective beam 11 is emitted. Therefore, all defect correction can function effectively.

### Third Embodiment

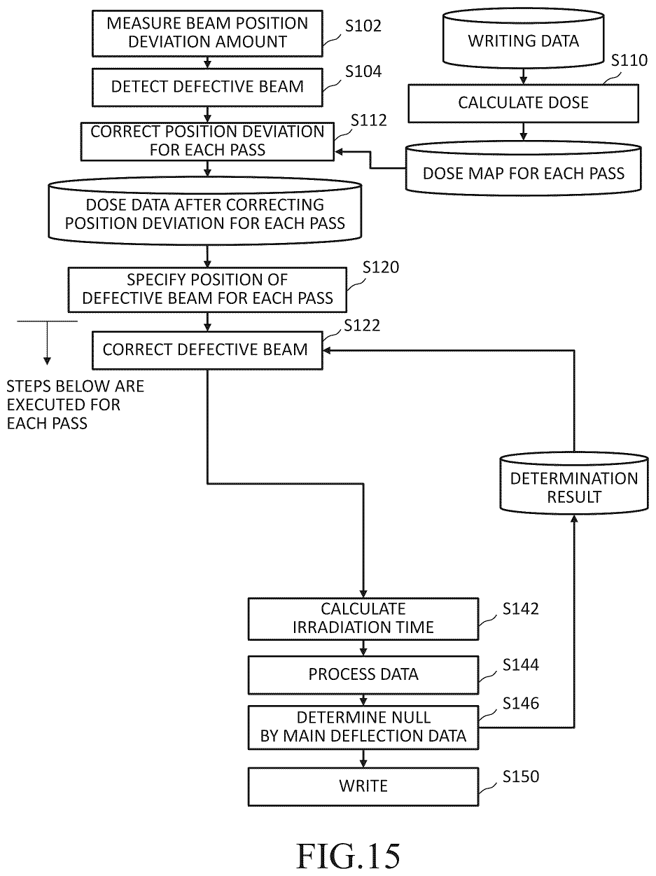

FIG. 15 is an illustration showing a flowchart of main steps of a writing method according to a third embodiment. FIG. 15 is the same as FIG. 8 except that a determination result of the main deflection data NULL determination step (S146) is stored in a storage device, and a determination result of the main deflection data NULL determination step (S146) is fed back.

The configuration of the writing apparatus according to the third embodiment is the same as that of FIG. 1. However, in the third embodiment, the finite dose determination unit 62 and the dose-data-for-defect generation unit 64 may be omitted. The contents of the third embodiment are the same as those of the first embodiment except for what is particularly described below.

According to the third embodiment, determination results of the main deflection data NULL determination step (S146) are stored in the storage device 144.

In the defective beam correction step ($122), the defect correction unit 60 determines, in the second or subsequent writing pass in a plurality of writing passes of multiple writing, whether or not to correct, in the pass concerned, an excessive dose due to the defective beam 11, based on a result of a determination of whether a pattern to be arranged in the each rectangular region in a preceding writing pass exists. In other words, the defect correction unit 60 determines, in the second or subsequent writing pass in a plurality of writing passes of multiple writing, whether or not to correct, in the pass concerned, an excessive dose due to the defective beam 11, based on a determination result of “with or without” a pattern determined in the main deflection data NULL determination step (S146) for each rectangular region in the preceding pass. For example, it can be known whether a defective beam has been emitted in the first writing pass or not, based on a determination result of “with or without” a pattern determined in the main deflection data NULL determination step (S146). Therefore, based on the determination result, if a defective beam has been emitted in the first writing pass, defect correction is performed in the second writing pass, for example. If a defective beam has not been emitted in the first writing pass, defect correction is not performed in the second writing pass. Thereby, it is possible to avoid an unnecessary defect correction.

### Fourth Embodiment

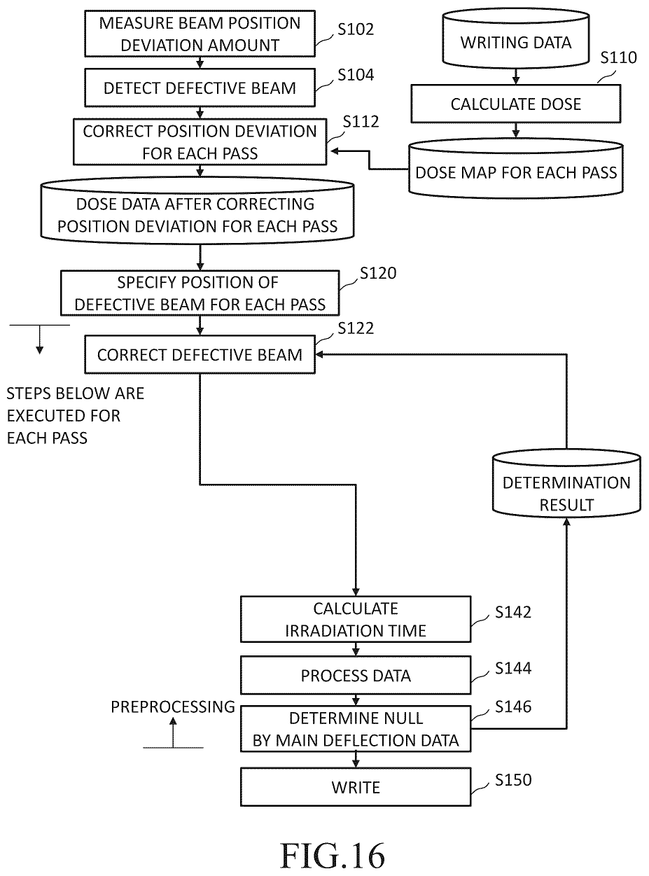

FIG. 16 is an illustration showing a flowchart of main steps of a writing method according to a fourth embodiment. FIG. 16 is the same as FIG. 15 except that each step from the beam-position deviation amount measurement step (S102) to the main deflection data NULL determination step (S146) in all the writing passes is performed as preprocessing before starting the writing processing in the first writing pass. Therefore, the respects that determination results in the main deflection data NULL determination step (S146) are stored in the storage device 144, and that the determination results in the main deflection data NULL determination step (S146) are fed back are the same as those of the third embodiment.

The configuration of the writing apparatus according to the fourth embodiment is the same as that of FIG. 1. However, in the fourth embodiment, the finite dose determination unit 62 and the dose-data-for-defect generation unit 64 may be omitted. The contents of the fourth embodiment are the same as those of the first embodiment except for what is particularly described below.

According to the fourth embodiment, each step from the beam-position deviation amount measurement step (S102) to the main deflection data NULL determination step (S146) in all the writing passes is performed as preprocessing before starting the writing processing in the first writing pass. Therefore, determination of “with or without” a pattern for each rectangular region 13 is performed as preprocessing before starting the writing processing.

Thereby, in the defective beam correction step (S122), the defect correction unit 60 can know, for each writing pass, whether a defective beam has been emitted in other writing pass, based on a determination result of “with or without” a pattern determined in the main deflection data NULL determination step (S146). Therefore, using the determination result of “with or without” a pattern in the main deflection data NULL determination step (S146), the defect correction unit 60 determines whether or not to correct, in the pass concerned, an excessive dose resulting from the defective beam 11. According to the fourth embodiment, before starting the writing processing in the first writing pass, it is possible to obtain determination results of “with or without” a pattern, with respect to all the writing passes, determined in the main deflection data NULL determination step (S146). Therefore, according to the fourth embodiment, it can also be determined whether a defective beam will be emitted in a posterior writing pass to be performed later. Consequently, for example, it is possible to determine, in the first writing pass, whether or not to perform correction of a defective beam to be emitted in the second writing pass.

### Fifth Embodiment

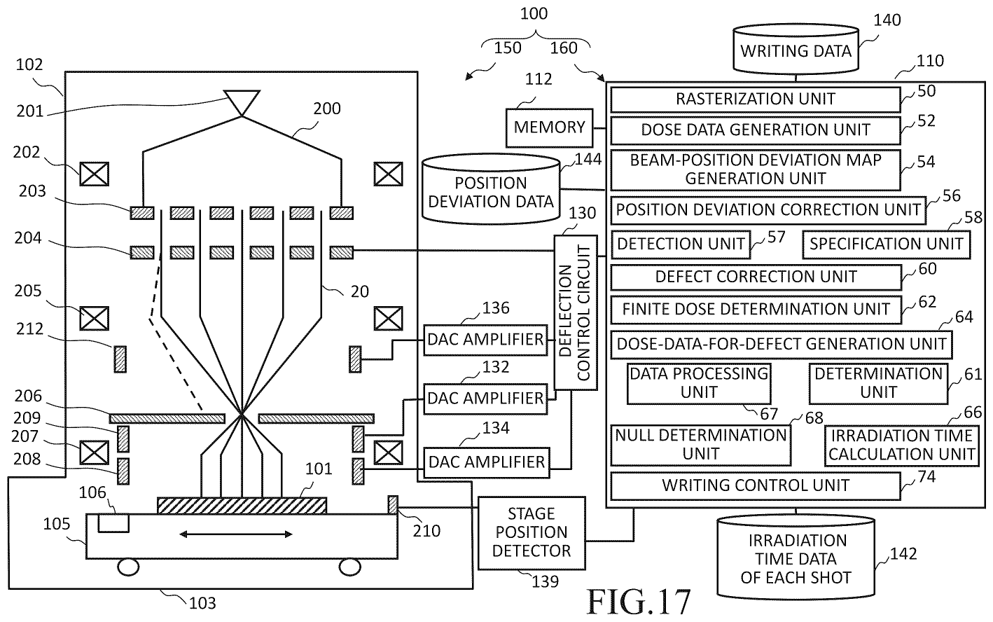

FIG. 17 is a conceptual diagram showing a configuration of a writing apparatus according to a fifth embodiment. FIG. 17 is the same as FIG. 1 except that a determination unit 61 is further added in the control computer 110. Each of the “ . . . units” such as the rasterization unit 50, the dose data generation unit 52, the beam-position deviation map generation unit 54, the position deviation correction unit 56, the detection unit 57, the specification unit 58, the defect correction unit 60, the determination unit 61, the finite dose determination unit 62, the dose-data-for-defect generation unit 64, the irradiation time calculation unit 66, the data processing unit 67, the NULL determination unit 68, and the writing control unit 74 includes processing circuitry. The processing circuitry includes, for example, an electric circuit, computer, processor, circuit board, quantum circuit, or semiconductor device. Each “ . . . unit” may use common processing circuitry (the same processing circuitry), or different processing circuitry (separate processing circuitry). Information input/output to/from the rasterization unit 50, the dose data generation unit 52, the beam-position deviation map generation unit 54, the position deviation correction unit 56, the detection unit 57, the specification unit 58, the defect correction unit 60, the determination unit 61, the finite dose determination unit 62, the dose-data-for-defect generation unit 64, the irradiation time calculation unit 66, the data processing unit 67, the NULL determination unit 68, and the writing control unit 74, and information being operated are stored in the memory 112 each time.

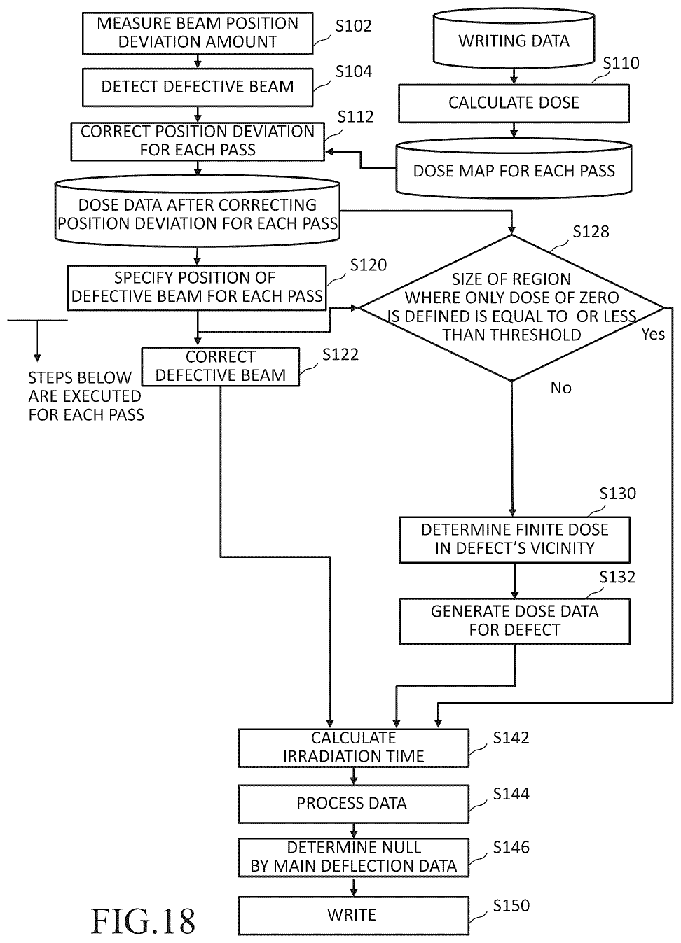

FIG. 18 is an illustration showing a flowchart of main steps of a writing method according to the fifth embodiment. FIG. 18 is the same as FIG. 8 except that a determination step (S128) is added before the defect's vicinity finite dose determination step (S130).

The contents of the fifth embodiment are the same as those of the first embodiment except for what is particularly described below.

The contents of each step of the beam-position deviation amount measurement step (S102), the defective beam detection step (S104), the dose calculation step (S110), the position deviation correction step (S112) for each pass, the defective beam position specification step (S120) for each pass, and the defective beam correction step (S122) are the same as those of the first embodiment.

In the determination step (S128), the determination unit 61 determines whether the size of the region where only the dose of zero is defined is equal to or less than a threshold. Specifically, referring to dose data after correcting a position deviation for each pass, the determination unit 61 determines whether the size of the region where only the dose of zero is defined is equal to or less than 1/n or equal to or less than n times of the rectangular region. “n” is a natural number. If the size of the region where only the dose of zero is defined is not less than nor equal to a threshold, it proceeds to the defect's vicinity finite dose determination step (S130). If the size of the region where only the dose of zero is defined is less than or equal to a threshold, it proceeds to the irradiation time calculation step (S142) skipping the defect's vicinity finite dose determination step (S130) and the dose-data-for-defect generation step (S132). In other words, the defect's vicinity finite dose determination step (S130) and the dose-data-for-defect generation step (S132) are performed only for a certain size region without a pattern.

The contents of each step after the defect's vicinity finite dose determination step (S130) are the same as those of the first embodiment. In the case of skipping the defect's vicinity finite dose determination step (S130) and the dose-data-for-defect generation step (S132), it is preferable to configure to always determine to be non-NULL (with a pattern) in the main deflection data NULL determination step (S146).

As described above, skipping a small region in regions having no pattern leads to reduction of the writing processing time.

Embodiments have been explained referring to specific examples described above. However, the present invention is not limited to these specific examples. The above examples describe the case where each beam of the multiple beams 20 individually controls the irradiation time within the maximum irradiation time Ttr for one shot. However, it is not limited thereto. For example, the maximum irradiation time Ttr for one shot is divided into a plurality of sub-shots each having a different irradiation time. Then, for each beam, a combination of sub-shots is selected from the plurality of sub-shots in order that the combination may become the irradiation time for one shot. It is also preferable to control the irradiation time for one shot of each beam, by continuously applying selected sub-shots using the same beam to the same pixel.

While the case of inputting a 10-bit control signal for controlling each control circuit 41 has been described above, the number of bits may be suitably set. For example, a 2-bit (or any one of 3 to 9 bit) control signal may be used. Alternatively, a control signal of 11 bits or more may be used.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Any multiple charged particle beam writing apparatus and multiple charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple charged particle beam writing apparatus comprising:
a beam forming mechanism configured to form multiple charged particle beams;
a dose data generation circuit configured to generate, for each processing region of a plurality of processing regions obtained by dividing a writing region on a surface of a target object, dose data which defines an individual dose of each position in a processing region concerned;
a dose determination circuit configured to perform, for the each processing region, a determination of whether a position where a dose of a nonzero value is defined exists in a vicinal region including a defect position to be irradiated with a defective beam whose dose is excessive in the multiple charged particle beams;
a dose-data-for-defect-position generation circuit configured to generate dose-data-for-defect which defines a dose for a defect at the defect position in a case where the dose of the nonzero value is defined in the vicinal region;
a pattern existence determination circuit configured to perform, for each unit region on the surface of the target object where an irradiation region of the multiple charged particle beams is set, a determination of whether a pattern to be arranged in a unit region concerned exists, using dose data of each position to be irradiated in the unit region concerned; and
a writing mechanism configured to perform writing a pattern on the target object using the multiple charged particle beams, wherein,
in a case of performing the writing, a unit region in which writing processing is to be performed is moved to a next unit region in which a pattern was determined to exist, skipping a unit region in which no pattern was determined to exist by the pattern existence determination circuit, and correction is performed to reduce an excessive dose, resulting from the defective beam at any writing pass in a plurality of writing passes of multiple writing, at another writing pass.

2. The apparatus according to claim 1, further comprising:
a stage configured to be movable and place thereon the target object; and
a tracking deflector configured to perform a tracking deflection of the multiple charged particle beams so that the irradiation region of the multiple charged particle beams follows movement of the stage, wherein
the unit region is set for each tracking control by the tracking deflection.

3. The apparatus according to claim 1, wherein
the pattern existence determination circuit determines that a pattern to be arranged in the each unit region exists.

4. The apparatus according to claim 1, further comprising:
a storage device configured to store a result of a determination of whether a pattern to be arranged in the each unit region exists,
wherein
in a second and subsequent writing passes in the plurality of writing passes of the multiple writing, a determination is performed whether to correct, in a writing pass concerned, the excessive dose resulting from the defective beam, based on a result of a determination of whether a pattern to be arranged in the each unit region in a preceding writing pass exists.

5. The apparatus according to claim 1, wherein
the determination of whether a pattern to be arranged in the each unit region exists is performed as preprocessing before starting writing processing.

6. The apparatus according to claim 1, further comprising:
a specification circuit configured to specify, for each writing pass, a position irradiated with an excessive dose defective beam including an “always ON” defective beam, with respect to each position in the unit region on the surface of the target object where the irradiation region of the multiple charged particle beams is set.

7. The apparatus according to claim 1, further comprising:
a defect correction circuit configured to perform correction for each writing pass by distributing an excessive dose, which has become excessive due to irradiation of an excessive dose defective beam at a writing pass other than a writing pass concerned, to peripheral beams.

8. The apparatus according to claim 1, further comprising:
a determination circuit configured to determine, for each writing pass, whether a size of a region where only a dose of zero is defined is one of being 1/n and being one of less than and equal to n times of a rectangular region, wherein
in a case in which the size of the region where only the dose of zero is defined is not less than nor equal to a threshold, the dose determination circuit determines whether the position where the dose of the nonzero value is defined exists in the vicinal region including the defect position to be irradiated with the defective beam.

9. A multiple charged particle beam writing method comprising:
forming multiple charged particle beams;
generating, for each processing region of a plurality of processing regions obtained by dividing a writing region on a surface of a target object, dose data which defines an individual dose of each position in a processing region concerned;
performing, for the each processing region, a determination of whether a position where a dose of a nonzero value is defined exists in a vicinal region including a defect position to be irradiated with a defective beam whose dose is excessive in the multiple charged particle beams;
generating dose-data-for-defect which defines a dose for a defect at the defect position in a case where the dose of the nonzero value is defined in the vicinal region;
performing, for each unit region on the surface of the target object where an irradiation region of the multiple charged particle beams is set, a determination of whether a pattern to be arranged in a unit region concerned exists, using dose data of each position to be irradiated in the unit region concerned; and
performing writing a pattern on the target object using the multiple charged particle beams, wherein,
in a case of the performing writing, a unit region in which writing processing is to be performed is moved to a next unit region in which a pattern was determined to exist, skipping a unit region in which no pattern was determined to exist, and correction is performed to reduce an excessive dose, resulting from the defective beam at any writing pass in a plurality of writing passes of multiple writing, at another writing pass.

10. The method according to claim 9, further comprising:
performing a tracking deflection of the multiple charged particle beams so that the irradiation region of the multiple charged particle beams follows movement of a stage which is movable and on which the target object is placed, wherein
the unit region is set for each tracking control by the tracking deflection.
